(19) United States
(12) Patent Application Publication
(10) Pub. No.: US 2022/0209214 A1
(43) Pub. Date: Jun. 30, 2022

(54) MANUFACTURING APPARATUS FOR SOLID-STATE SECONDARY BATTERY AND METHOD FOR MANUFACTURING SOLID-STATE SECONDARY BATTERY

(71) Applicant: SEMICONDUCTOR ENERGY LABORATORY CO., LTD., ATSUGI-SHI, KANAGAWA-KEN (JP)

(72) Inventors: Kazutaka KURIKI, Ebina, Kanagawa (JP); Ryota TAJIMA, Isehara, Kanagawa (JP); Yumiko YONEDA, Isehara, Kanagawa (JP); Shunpei YAMAZAKI, Setagaya, Tokyo (JP)

(21) Appl. No.: 17/606,861

(22) PCT Filed: Apr. 16, 2020
(86) PCT No.: PCT/IB2020/053579

§ 371 Date: Oct. 27, 2021

(30) Foreign Application Priority Data
Apr. 30, 2019 (JP) 2019-087082

(51) Int. Cl. H01M 4/04; C23C 14/04; H01M 10/0562; H01M 10/0585

(52) U.S. Cl. CPC H01M 4/0426; H01M 10/0585; H01M 10/0562; C23C 14/042

(57) ABSTRACT

An object is to achieve a manufacturing apparatus that can fully automate the manufacturing of a solid-state secondary battery. A mask alignment chamber, a first transfer chamber connected to the mask alignment chamber, a second transfer chamber connected to the first transfer chamber, a first film formation chamber connected to the second transfer chamber, a third transfer chamber connected to the first transfer chamber, and a second film formation chamber connected to the third transfer chamber are included. The first film formation chamber has a function of forming a positive electrode active material layer or a negative electrode active material layer by a sputtering method, the second film formation chamber has a function of forming a solid electrolyte layer by co-evaporation of an organic complex of lithium and SiOx (0<x≤2), and a substrate is transferred between the mask alignment chamber and the first film formation chamber and between the mask alignment chamber and the second film formation chamber without being exposed to the air.

### TECHNICAL FIELD

One embodiment of the present invention relates to an object, a method, or a manufacturing method. Alternatively, the present invention relates to a process, a machine, manufacture, or a composition (composition of matter). One embodiment of the present invention relates to a semiconductor device, a display device, a light-emitting device, a power storage device, a lighting device, an electronic device, or a manufacturing method thereof. In particular, one embodiment of the present invention relates to a method for manufacturing a power storage device and a manufacturing apparatus therefor.

Note that electronic devices in this specification generally mean devices including power storage devices, and electro-optical devices including power storage devices, information terminal devices including power storage devices, and the like are all electronic devices.

### BACKGROUND ART

Electronic devices carried around by users and electronic devices worn by users have been actively developed.

Electronic devices carried around by users and electronic devices worn by users operate using primary batteries or secondary batteries, which are examples of power storage devices, as power sources. It is desired that electronic devices carried around by users be used for a long time; thus, a high-capacity secondary battery is used. Since high-capacity secondary batteries are large in size, there is a problem in that their incorporation in electronic devices increases the weight of the electronic devices. In view of the problem, development of small or thin high-capacity secondary batteries that can be incorporated in portable electronic devices is being pursued.

A lithium-ion secondary battery using an electrolyte solution such as an organic solvent as a transmission medium for lithium ions serving as carrier ions is widely used. However, a secondary battery using liquid has problems of the operable temperature range, decomposition reaction of an electrolyte solution by a potential to be used, and liquid leakage to the outside of the secondary battery since the secondary battery uses liquid. In addition, a secondary battery using an electrolyte solution has a risk of ignition due to liquid leakage.

A fuel battery is a secondary battery using no liquid; however, noble metals are used for the electrodes, and a material of a solid electrolyte is also expensive.

In addition, as a secondary battery using no liquid, a power storage device using a solid electrolyte, which is called a solid-state battery, is known. For example, Patent Document 1 is disclosed.

Patent Document 1 discloses an example in which a lithium cobalt oxide film is formed over a positive electrode current collector by a sputtering method.

### REFERENCE

### Patent Document

[Patent Document 1] U.S. Pat. No. 8,404,001

### SUMMARY OF THE INVENTION

### Problems to be Solved by the Invention

An object is to achieve a manufacturing apparatus that can fully automate the manufacturing of a solid-state secondary battery. Another object is to achieve a manufacturing apparatus that can manufacture a solid-state secondary battery in a short time. Another object is to achieve a manufacturing apparatus that can manufacture a solid-state secondary battery with high yield.

Another object is to provide a method for manufacturing a solid-state secondary battery without exposure to the air.

### Means for Solving the Problems

A structure of a manufacturing apparatus disclosed in this specification is a manufacturing apparatus for a solid-state secondary battery which includes a mask alignment chamber, a first transfer chamber connected to the mask alignment chamber, a second transfer chamber connected to the first transfer chamber, a first film formation chamber connected to the second transfer chamber, a third transfer chamber connected to the first transfer chamber, and a second film formation chamber connected to the third transfer chamber. In the first film formation chamber, a positive electrode active material layer or a negative electrode active material layer are formed by a sputtering method. In the second film formation chamber, a solid electrolyte layer is formed by co-evaporation of an organic complex of lithium and SiOx (0<X≤2). A substrate is transferred between the mask alignment chamber and the first film formation chamber and between the mask alignment chamber and the second film formation chamber without being exposed to the air.

In the above-described structure, a structure further including a heating chamber connected to the second transfer chamber may be employed. The heating chamber is preferably kept at a pressure lower than an atmospheric pressure (a reduced pressure atmosphere) by an exhaust mechanism before and after heat treatment. With a higher degree of vacuum, water or the like adsorbed on a surface of an insulating film can be released more efficiently. For example, the pressure in the chamber for the heat treatment when the substrate is inserted is higher than or equal to 1×10⁻⁷ Pa and lower than or equal to 1×10⁻³ Pa, preferably higher than or equal to 1×10⁻⁶ Pa and lower than or equal to 1×10⁻⁴ Pa.

With the above-described structure, the cleanliness of the film formation chambers and the transfer chambers can be maintained, whereby a solid-state secondary battery having favorable characteristics can be manufactured.

In the above-described first film formation chamber, the back pressure (total pressure) is set to lower than or equal to 1×10⁻⁴ Pa, preferably lower than or equal to 3×10⁻⁵ Pa, further preferably lower than or equal to 1×10⁻⁵ Pa by an exhaust mechanism. In the above-described first film formation chamber, the partial pressure of a gas molecule (atom) having a mass-to-charge ratio (m/z) of 18 is lower than or equal to 3×10⁻⁵ Pa, preferably lower than or equal to 1×10⁻⁵ Pa, further preferably lower than or equal to 3×10⁻⁶ Pa. Moreover, in the above-described first film formation chamber, the partial pressure of a gas molecule (atom) having a mass-to-charge ratio (m/z) of 28 is lower than or equal to 3×10⁻⁵ Pa, preferably lower than or equal to 1×10⁻⁵ Pa, further preferably lower than or equal to 3×10⁻⁶ Pa. Furthermore, in the above-described first film formation chamber, the partial pressure of a gas molecule (atom) having a mass-to-charge ratio (m/z) of 44 is lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in a vacuum chamber such as the first film formation chamber can be measured using a mass analyzer. For example, Qulee CGM-051, a quadrupole mass analyzer (also referred to as Q-mass) produced by ULVAC, Inc. can be used.

Furthermore, in the above-described structure, the transfer chambers may have a structure where exhaust is performed from an atmospheric pressure to a low vacuum or a medium vacuum (approximately several hundreds of Pa to 0.1 Pa) using a vacuum pump and then a valve is switched to perform exhaust from the medium vacuum to a high vacuum or an ultra-high vacuum (approximately 0.1 Pa to 1×10⁻⁷ Pa) using a cryopump.

Furthermore, a method for manufacturing a solid-state secondary battery is also one embodiment of the invention disclosed in this specification and includes forming a first conductive layer over and in contact with an insulating surface, forming a negative electrode active material layer over the first conductive layer, forming a solid electrolyte layer over the negative electrode active material layer by co-evaporation of an organic complex of lithium and SiOx (0<X≤2), forming a first positive electrode active material layer over the solid electrolyte layer, forming a second conductive layer over and in contact with the insulating surface and over the first positive electrode active material layer, and forming a second positive electrode active material layer over the second conductive layer. The solid electrolyte layer is in contact with a side surface of the negative electrode active material layer, the second conductive layer is in contact with a side surface of part of the solid electrolyte layer, and the first positive electrode active material layer and the second positive electrode active material layer do not overlap with each other.

When the same sputtering target is used for the first positive electrode active material layer and the second positive electrode active material layer in the above-described manufacturing method, the manufacturing cost can be reduced.

When the same sputtering target is used for the first conductive layer and the second conductive layer in the above-described manufacturing method, the manufacturing cost can be reduced.

In the above-described structure, the organic complex of lithium is any of an alkali metal, an alkaline earth metal, an organic complex of an alkali metal or an alkaline earth metal, and a compound thereof; and Li, Li₂O, or the like can be given for example. The organic complex of lithium is particularly preferable, and 8-hydroxyquinolinato-lithium (abbreviation: Liq), which has favorable characteristics, is especially preferable. As another organic material co-evaporated with SiOx (0<X≤2), dilithium phthalocyanine (phthalocyanine dilithium), lithium 2-(2-pyridyl)phenolate (abbreviation: Lipp), or lithium 2-(2′,2″-bipyridin-6′-yl)phenolate (abbreviation: Libpp) can be used.

### Effect of the Invention

A solid-state secondary battery is manufactured in an environment which impurities are difficult to enter without exposure to the air, so that a solid-state secondary battery having favorable characteristics can be manufactured.

### BRIEF DESCRIPTION OF THE DRAWINGS

FIG. 1 is a schematic top view of a manufacturing apparatus illustrating one embodiment of the present invention.

FIG. 2 is a cross-sectional view of part of the manufacturing apparatus illustrating one embodiment of the present invention.

FIG. 3A and FIG. 3B are atop view and a cross-sectional view, respectively, of a secondary battery illustrating one embodiment of the present invention.

FIG. 4A is a top view of a secondary battery of one embodiment of the present invention in the process of manufacturing, and FIG. 4B is a top view thereof after completion.

FIG. 5 is a cross-sectional view illustrating one embodiment of the present invention.

FIG. 6 is a manufacturing flow showing one embodiment of the present invention.

FIG. 7A is a perspective view of a battery cell, and FIG. 7B is a diagram illustrating an example of an electronic device.

FIG. 8A, FIG. 8B, and FIG. 8C are diagrams illustrating examples of electronic devices.

### MODE FOR CARRYING OUT THE INVENTION

Embodiments of the present invention are described in detail below with reference to the drawings. Note that the present invention is not limited to the following description, and it is readily understood by those skilled in the art that modes and details of the present invention can be modified in various ways. In addition, the present invention should not be construed as being limited to the description of the embodiments below.

### Embodiment 1

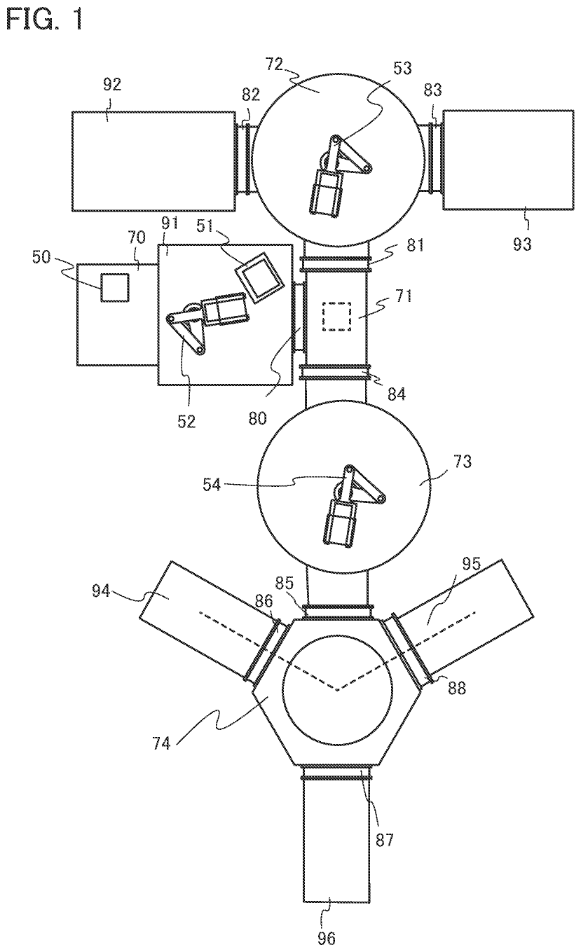

In this embodiment, an example of a multi-chamber manufacturing apparatus that can fully automate the manufacturing of a first electrode to a second electrode of a secondary battery is illustrated in FIG. 1.

FIG. 1 illustrates an example of a multi-chamber manufacturing apparatus provided with gates 80, 81, 82, 83, 84, 85, 86, 87, and 88, a load lock chamber 70, a mask alignment chamber 91, a first transfer chamber 71, a second transfer chamber 72, a third transfer chamber 73, a plurality of film formation chambers (a first film formation chamber 92 and a second film formation chamber 74), a heating chamber 93, a second material supply chamber 94, a first material supply chamber 95, and a third material supply chamber 96.

The mask alignment chamber 91 includes at least a stage 51 and a substrate transfer mechanism 52.

The first transfer chamber 71 includes a substrate cassette elevation mechanism, the second transfer chamber 72 includes a substrate transfer mechanism 53, and the third transfer chamber includes a substrate transfer mechanism 54.

The first film formation chamber 92, the second film formation chamber 74, the second material supply chamber 94, the first material supply chamber 95, the third material supply chamber 96, the mask alignment chamber 91, the first transfer chamber 71, the second transfer chamber 72, and the third transfer chamber 73 are connected to their respective exhaust mechanisms. As the exhaust mechanisms, exhaust devices appropriate for the uses of the chambers are selected; for example, an exhaust mechanism including a pump having an adsorption unit, such as a cryopump, a sputtering ion pump, or a titanium sublimation pump, an exhaust mechanism including a turbo molecular pump provided with a cold trap, and the like can be given.

Procedures for forming films over a substrate are as follows. A substrate 50 or a substrate cassette is set in the load lock chamber 70 and transferred to the mask alignment chamber 91 by the substrate transfer mechanism 52. In the mask alignment chamber 91, a mask to be used is picked up from a plurality of masks set in advance, and positional alignment with the substrate is performed over the stage 51. After the positional alignment is finished, the gate 80 is opened and a transfer to the first transfer chamber 71 is performed by the substrate transfer mechanism 52. The substrate is transferred to the first transfer chamber 71, the gate 81 is opened, and a transfer to the second transfer chamber 72 is performed by the substrate transfer mechanism 53.

The first film formation chamber 92 provided next to the second transfer chamber 72 with the gate 82 therebetween is a sputtering chamber. The sputtering chamber has a mechanism capable of applying a voltage to a sputtering target with a power supply that is switched between an RF power supply and a pulsed DC power supply. Two or three kinds of sputtering targets can be set. In this embodiment, a single crystal silicon target, a sputtering target whose main component is lithium cobalt oxide (LiCoO₂), and a titanium target are set. A substrate heating mechanism can be provided in the first film formation chamber 92 to perform film formation under heating conditions at a heater temperature of 700° C.

By a sputtering method using a single crystal silicon target, a negative electrode active material layer can be formed. In a negative electrode, an SiOx film formed by a reactive sputtering method using an Ar gas and an O₂ gas may also be used as a negative electrode active material layer. It is also possible to use a silicon nitride film formed by a reactive sputtering method using an Ar gas and an N₂ gas as a sealing film. Furthermore, a positive electrode active material layer can be formed by a sputtering method using a sputtering target whose main component is lithium cobalt oxide (LiCoO₂). By a sputtering method using a titanium target, a conductive film serving as a current collector can be formed. A titanium nitride film formed by a reactive sputtering method using an Ar gas and an N₂ gas can be used as a layer for preventing diffusion between a current collector layer and an active material layer.

In the case of forming a positive electrode active material layer, the mask and the substrate which are in the overlapping state are transferred from the second transfer chamber 72 to the first film formation chamber 92 by the substrate transfer mechanism 53, the gate 82 is closed, and film formation is performed by a sputtering method. After the film formation is finished, the gate 82 and the gate 83 are opened, a transfer to the heating chamber 93 is performed, the gate 83 is closed, and then heating can be performed. For heat treatment in the heating chamber 93, an RTA (Rapid Thermal Anneal) apparatus, a resistance heating furnace, or a microwave heating apparatus can be used. As the RTA apparatus, a GRTA (Gas Rapid Thermal Anneal) apparatus or an LRTA (Lamp Rapid Thermal Anneal) apparatus can be used. The heat treatment in the heating chamber 93 can be performed in an atmosphere of nitrogen, oxygen, a rare gas, or dry air. In addition, heating time is longer than or equal to 1 minute and shorter than or equal to 24 hours.

After the film formation or the heat treatment is finished, the substrate and the mask are transferred back to the mask alignment chamber 91, and positional alignment for a new mask is performed. After the positional alignment, the substrate and the mask are transferred to the first transfer chamber 71 by the substrate transfer mechanism 52. The substrate is carried by the elevation mechanism of the first transfer chamber 71, the gate 84 is opened, and a transfer to the third transfer chamber 73 is performed by the substrate transfer mechanism 54.

In the second film formation chamber 74 connected to the third transfer chamber 73 with the gate 85 therebetween, film formation by evaporation is performed.

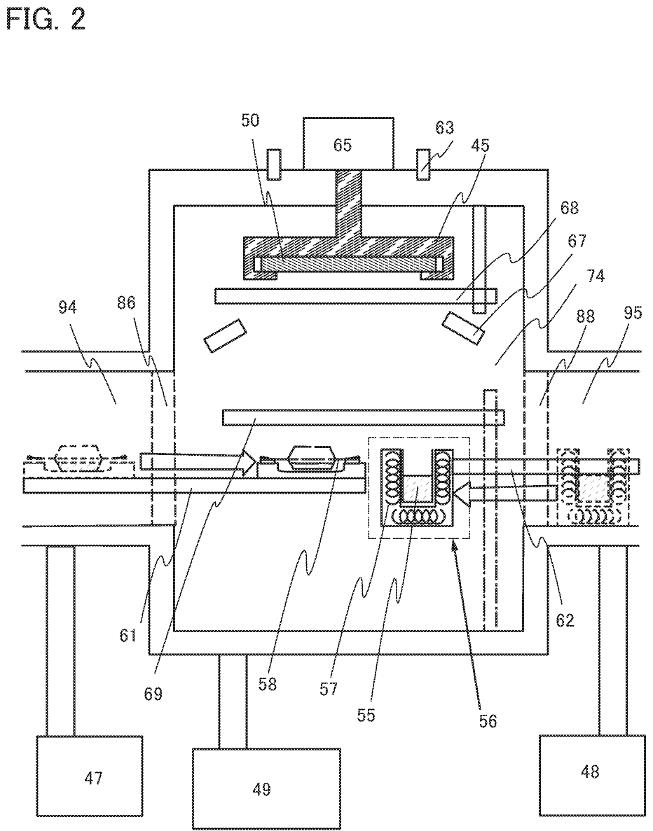

FIG. 2 illustrates an example of a cross-sectional structure of the structure of the second film formation chamber 74. A schematic cross-sectional view taken along a dotted line in FIG. 1 is FIG. 2. The second film formation chamber 74 is connected to an exhaust mechanism 49, and the first material supply chamber 95 is connected to an exhaust mechanism 48. The second material supply chamber 94 is connected to an exhaust mechanism 47. The second film formation chamber 74 illustrated in FIG. 2 is an evaporation chamber where vapor deposition is performed with an evaporation source 56 moved from the first material supply chamber 95; evaporation sources are moved from the plurality of material supply chambers, so that evaporation in which a plurality of substances are vaporized at the same time, that is, co-evaporation is possible. In FIG. 2, an evaporation source having an evaporation boat 58 moved from the second material supply chamber 94 is also illustrated.

Furthermore, the second film formation chamber 74 is connected to the second material supply chamber 94 with the gate 86 therebetween. The second film formation chamber 74 is connected to the first material supply chamber 95 with the gate 88 therebetween. The second film formation chamber 74 is connected to the third material supply chamber 96 with the gate 87 therebetween. Accordingly, the second film formation chamber 74 is capable of three-source co-evaporation.

Procedures for performing evaporation are as follows. The substrate is set on a substrate holding portion 45. The substrate holding portion 45 is connected to a rotation mechanism 65. A first evaporation material 55 is heated to some extent in the first material supply chamber 95, and when the evaporation rate is stabilized, the gate 88 is opened, and an arm 62 is extended to move the evaporation source 56 to a position under the substrate. The evaporation source 56 is composed of the first evaporation material 55, a heater 57, and a container in which the first evaporation material 55 is stored. Furthermore, a second evaporation material is also heated to some extent in the second material supply chamber 94, and when the evaporation rate is stabilized, the gate 86 is opened and an arm 61 is extended to move the evaporation source to a position under the substrate.

Then, a shutter 68 and a shutter 69 for evaporation sources are opened and co-evaporation is performed. The rotation mechanism 65 is rotated during evaporation to increase the uniformity in the film thickness. After the evaporation is finished, the substrate is transferred to the mask alignment chamber 91 through the same route. In the case of taking out the substrate from the manufacturing apparatus, the substrate is transferred from the mask alignment chamber 91 to the load lock chamber 70 and then taken out.

Furthermore, FIG. 2 illustrates, as an example, a state where the substrate 50 and a mask are held by the substrate holding portion 45. The substrate 50 (and the mask) is rotated by the substrate rotation mechanism, so that uniformity of film formation can be increased. The substrate rotation mechanism may also serve as a substrate transfer mechanism.

Moreover, the second film formation chamber 74 may be provided with an imaging unit 63 such as a CCD camera. With the imaging unit 63, the position of the substrate 50 can be checked.

Furthermore, in the second film formation chamber 74, the thickness of a film formed on a substrate surface can be estimated from a result of measurement with a film thickness measurement mechanism 67. The film thickness measurement mechanism 67 may be provided with a crystal oscillator, for example.

Note that in order to control vapor deposition of vaporized evaporation materials, the shutter 68, which overlaps with the substrate, and the shutter 69 for evaporation sources, which overlaps with the evaporation source 56 and the evaporation boat 58, are provided until the vaporizing rate of the evaporation materials is stabilized.

Although an example of resistance heating evaporation is shown for the evaporation source 56, EB (Electron Beam) evaporation may also be employed. Although an example using a crucible as the container of the evaporation source 56 is illustrated, an evaporation boat may be used as well. An organic material, which is the first evaporation material 55, is put in the crucible heated by the heater 57. In the case where pellets or particles of SiO or the like are used as the evaporation material, the evaporation boat 58 is used. The evaporation boat 58 consists of three parts, in which a member having a concave portion, a middle lid with two holes, and a top lid with a hole are overlapped. Note that the middle lid may be removed to perform evaporation. The evaporation boat 58 serves as resistance by being energized and the evaporation boat is heated by itself.

Although an example of a multi-chamber apparatus is described in this embodiment, without particular limitation, the manufacturing apparatus may be of an in-line type.

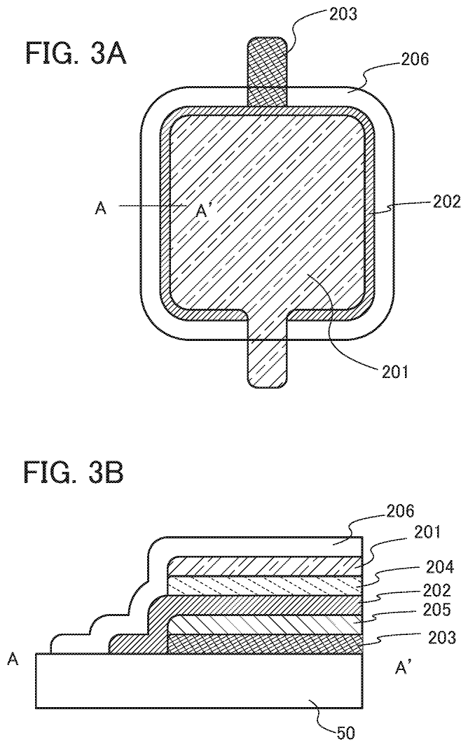

An example of manufacturing a secondary battery with the evaporation apparatus illustrated in FIG. 1 and FIG. 2 is described below with reference to FIG. 3A and FIG. 3B. FIG. 3A is a top view of a secondary battery, and FIG. 3B corresponds to a cross-sectional view taken along a line AA′ in FIG. 3A.

As illustrated in FIG. 3B, a negative electrode current collector 203 is formed over the substrate 50, and a negative electrode active material layer 205, a solid electrolyte layer 202, a positive electrode active material layer 204, a positive electrode current collector 201, and a protective layer 206 are stacked in this order over the negative electrode current collector 203. The thickness of each film is more than or equal to 10 nm and less than or equal to 10 μm, preferably more than or equal to 100 nm and less than or equal to 2 μm.

These films can each be formed using a metal mask. By using the same metal mask for the negative electrode current collector 203 and the negative electrode active material layer 205 and using the same metal mask for the positive electrode current collector 201 and the positive electrode active material layer 204, a secondary battery can be manufactured with four different metal masks.

First, the substrate 50 is set in the load lock chamber 70 illustrated in FIG. 1 and transferred to the mask alignment chamber 91. Positional alignment with a first metal mask is performed in the mask alignment chamber 91. Then, a transfer to the first film formation chamber 92 is performed through the transfer chamber 71 and the transfer chamber 72, and a titanium film that is the negative electrode current collector 203 and a silicon film that is the negative electrode active material layer 205 are selectively formed by a sputtering method.

Examples of the substrate 50 include a quartz substrate, a glass substrate, and a plastic substrate which have an insulating surface. Alternatively, a semiconductor substrate having an insulating surface can be used. A circuit such as a semiconductor element may be formed in advance on the semiconductor substrate and electrically connected to the secondary battery which is formed later.

After film formation of the negative electrode current collector 203 and the negative electrode active material layer 205 is finished, a transfer back to the mask alignment chamber 91 is performed, and positional alignment with a second metal mask is performed. Then, a transfer to the second film formation chamber 74 is performed through the transfer chamber 71 and the transfer chamber 73, and the solid electrolyte layer 202 is selectively formed by an evaporation method.

In the second film formation chamber 74, the solid electrolyte layer 202 is formed by co-evaporation of a Si powder (e.g., SiO, SiO₂, a mixture of SiO and SiO₂) and a Liq powder. Liq is an organic complex of lithium and refers to 8-hydroxyquinolinato-lithium. Note that a resistance heating source or an electron beam evaporation source is used for the co-evaporation. Note that without limitation to a Si powder (SiO), one with a pellet shape or a particle shape may be used.

After film formation of the solid electrolyte layer 202 is finished, a transfer back to the mask alignment chamber 91 is performed, and positional alignment with a third metal mask is performed. Then, a transfer to the first film formation chamber 92 is performed through the transfer chamber 71 and the transfer chamber 72, and a LiCoO₂ film that is the positive electrode active material layer 204 and a titanium film that is the positive electrode current collector 201 are selectively formed by a sputtering method.

After film formation of the positive electrode active material layer 204 and the positive electrode current collector 201 is finished, a transfer back to the mask alignment chamber 91 is performed, and positional alignment with a fourth metal mask is performed. Then, a transfer to the first film formation chamber 92 is performed through the transfer chamber 71 and the transfer chamber 72, and a silicon nitride film (also referred to as a SiN film) serving as the protective layer 206 is selectively formed by a sputtering method with a single crystal silicon target in a nitrogen atmosphere.

As illustrated in FIG. 3A, part of the negative electrode current collector 203 is exposed to form a negative electrode terminal portion. A region other than the negative electrode terminal portion is covered with the protective layer 206. In addition, part of the positive electrode current collector 201 is exposed to form a positive electrode terminal portion. A region other than the positive electrode terminal portion is covered with the protective layer 206.

After film formation of the protective layer 206 is finished, a transfer back to the mask alignment chamber 91 and further to the load lock chamber 70 is performed, and then the substrate on which the secondary battery is formed is taken out.

A thin-film-type solid-state secondary battery illustrated in FIG. 3A and FIG. 3B can be manufactured through a series of processes described above with the evaporation apparatus illustrated in FIG. 1 and FIG. 2.

Furthermore, when solid-state secondary batteries are stacked, the capacity can be increased, and thin-film-type solid-state secondary batteries connected in parallel can be manufactured. In the case of stacking solid-state secondary batteries, a positive electrode active material layer is formed in contact with both surfaces of a positive electrode, and a negative electrode active material layer is formed in contact with both surfaces of a negative electrode.

### Embodiment 2

Solid-state secondary batteries can be connected in series in order to increase the output voltage of the solid-state secondary batteries. Although the example of the single-layer cell is described in Embodiment 1, an example of manufacturing solid-state secondary batteries connected in series is described in this embodiment.

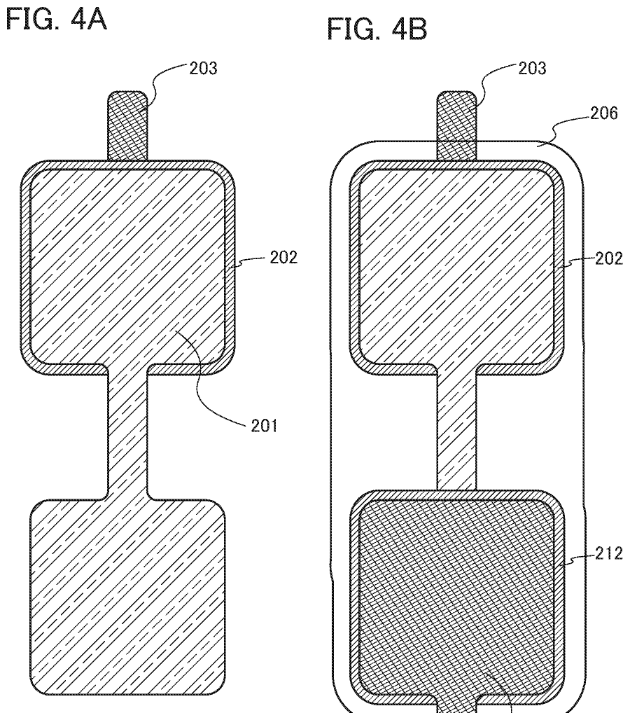

FIG. 4A is a top view right after formation of a first solid-state secondary battery, and FIG. 4B is a top view of two solid-state secondary batteries connected in series. In FIG. 4A and FIG. 4B, the same portions as the portions in FIG. 3 described in Embodiment 1 are denoted by the same reference numerals.

FIG. 4A illustrates the state right after formation of the positive electrode current collector 201. The shape of the top surface of the positive electrode current collector 201 is different from that in FIG. 3. The positive electrode current collector 201 illustrated in FIG. 4A is partly in contact with a side surface of the solid electrolyte layer and is also in contact with an insulating surface of the substrate. This insulating surface is also in contact with the negative electrode of the first secondary battery.

Then, a second positive electrode active material layer is formed over a region which is in the positive electrode current collector 201 and does not overlap with a first positive electrode active material layer. Then, a second solid electrolyte layer 212 is formed, and a second negative electrode active material layer and a second negative electrode current collector 213 are formed thereover. Lastly, the protective layer 206 is formed as illustrated in FIG. 4B.

FIG. 4B illustrates a structure in which two solid-state secondary batteries are arranged on a plane and connected in series.

A plurality of thin-film-type solid-state secondary batteries connected in series can be manufactured without exposure to the air by using the manufacturing apparatus illustrated in FIG. 1 and FIG. 2.

### Embodiment 3

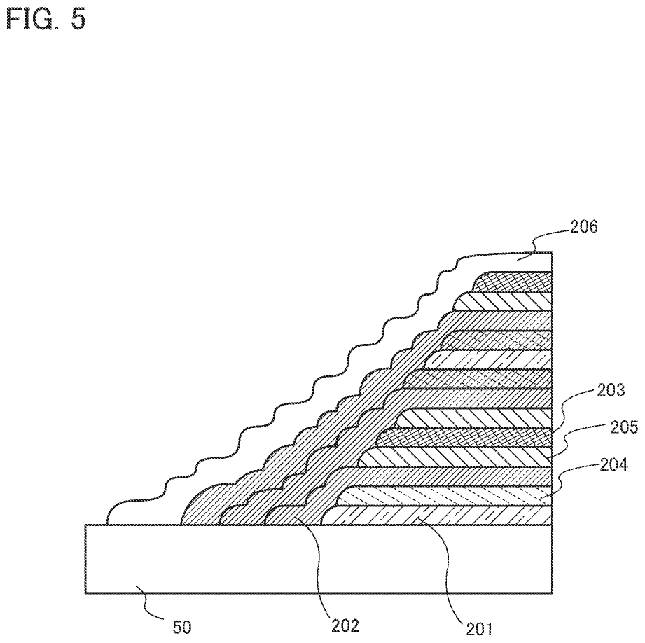

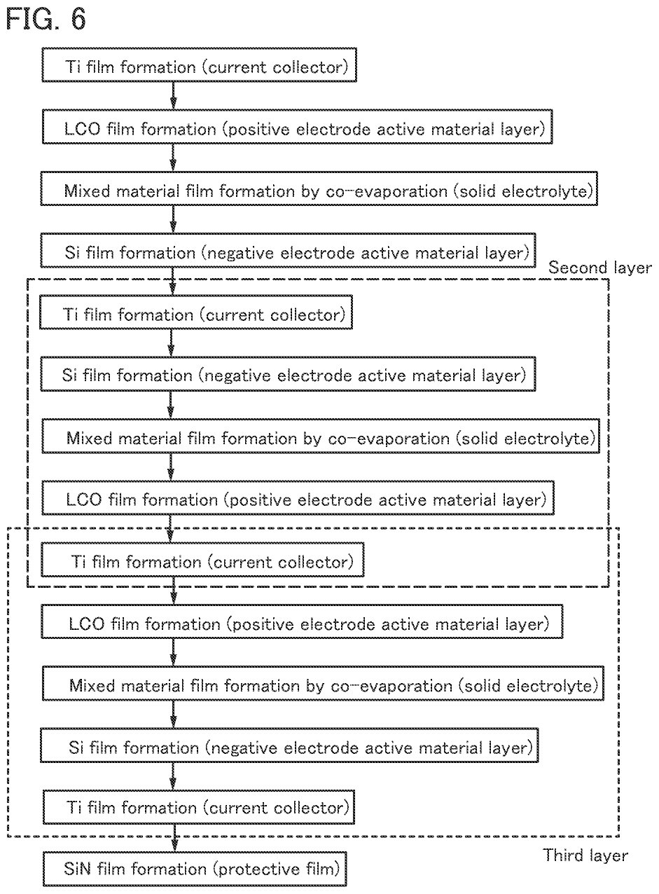

An example of the single-layer cell is described in Embodiment 1, whereas an example of a multi-layer cell is described in this embodiment. FIG. 5 and FIG. 6 illustrate one of embodiments describing the case of a multi-layer cell of a thin-film-type solid-state secondary battery.

FIG. 5 illustrates an example of a cross section of a three-layer cell.

A first cell is formed in such a manner that the positive electrode current collector 201 is formed over the substrate 50, and the positive electrode active material layer 204, the solid electrolyte layer 202, the negative electrode active material layer 205, and the negative electrode current collector 203 are sequentially formed over the positive electrode current collector 201.

Furthermore, a second cell is formed in such a manner that a second negative electrode active material layer, a second solid electrolyte layer, a second positive electrode active material layer, and a second positive electrode are sequentially formed over the negative electrode current collector 203.

Moreover, a third cell is formed in such a manner that a third positive electrode active material layer, a third solid electrolyte layer, a third negative electrode active material layer, and a third negative electrode are sequentially formed over the second positive electrode.

Lastly, the protective layer 206 is formed in FIG. 5. The three-layer stack illustrated in FIG. 5 has a structure of series connection in order to increase the voltage but can be connected in parallel with an external wiring. Series connection, parallel connection, or series-parallel connection can also be selected with an external wiring.

Note that the solid electrolyte layer 202, the second solid electrolyte layer, the third solid electrolyte layer are preferably formed using the same material in order to reduce the manufacturing cost.

FIG. 6 illustrates an example of a manufacturing flow for obtaining the structure illustrated in FIG. 5.

In FIG. 6, an LCO film is used as the positive electrode active material layer, a titanium film is used as the current collector (conductive layer), and the titanium film is regarded as the positive electrode in order to reduce manufacturing steps. Furthermore, a silicon film is used as the negative electrode active material layer, and a titanium film is used as the current collector (conductive layer) and regarded as the negative electrode. The use of the titanium film as a common electrode allows a three-layer stacked cell with a small number of components to be achieved.

A multi-layer cell of a thin-film-type solid-state secondary battery can be manufactured without exposure to the air by using the manufacturing apparatus illustrated in FIG. 1 and FIG. 2.

This embodiment can be freely combined with Embodiment 1 or Embodiment 2.

### Embodiment 4

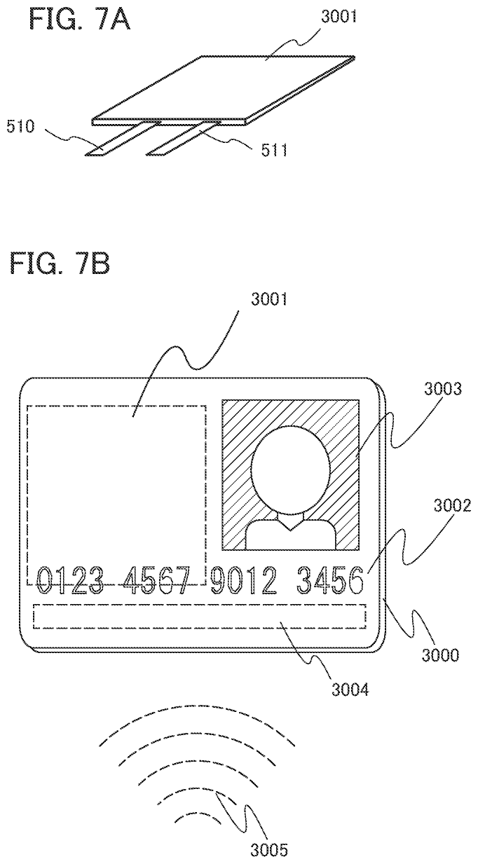

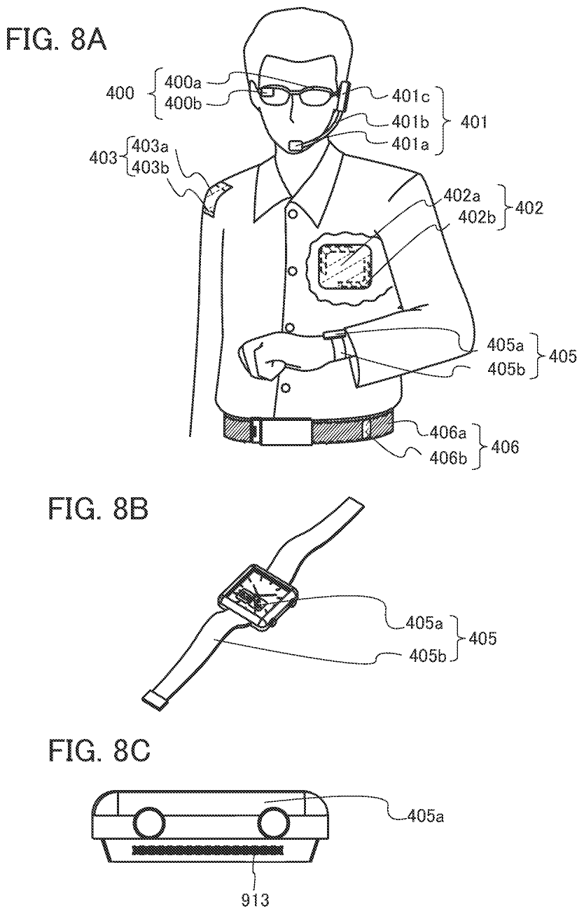

In this embodiment, examples of electronic devices using thin-film-type secondary batteries are described with reference to FIG. 7 and FIG. 8.

FIG. 7A is an external perspective view of a thin-film-type secondary battery 3001. Sealing with a laminate film or an insulating film is performed so that a positive electrode lead electrode 510 electrically connected to a positive electrode of the solid-state secondary battery and a negative electrode lead electrode 511 electrically connected to a negative electrode project.

FIG. 7B illustrates a card including an IC which is an example of an application device using a thin-film-type secondary battery of the present invention. The thin-film-type secondary battery 3001 can be charged with electric power obtained by power feeding from a radio wave 3005. In a card 3000 including an IC, an antenna, an IC 3004, and the thin-film-type secondary battery 3001 are provided. An ID 3002 and a photograph 3003 of a worker who wears the management badge are attached on the card 3000 including an IC. A signal such as an authentication signal can be transmitted from the antenna using the electric power charged in the thin-film-type secondary battery 3001.

An active matrix display device may be provided instead of the photograph 3003. As examples of the active matrix display device, a reflective liquid crystal display device, an organic EL display device, electronic paper, or the like can be given. An image (a moving image or a still image) or time can be displayed on the active matrix display device. Electric power for the active matrix display device can be supplied from the thin-film-type secondary battery 3001.

A plastic substrate is used for the card including an IC, and thus an organic EL display device using a flexible substrate is preferable.

Instead of the photograph 3003, a solar cell may be provided. When irradiation with external light is performed, light can be absorbed to generate electric power, and the thin-film-type secondary battery 3001 can be charged with the electric power.

Without limitation to the card including an IC, the thin-film-type secondary battery can be used for a power source of an in-vehicle wireless sensor, a secondary battery for a MEMS device, or the like.

FIG. 8A illustrates examples of wearable devices. A secondary battery is used as a power source of a wearable device. To have improved water resistance in daily use or outdoor use by a user, a wearable device is desirably capable of being charged wirelessly as well as being charged with a wire whose connector portion for connection is exposed.

For example, a secondary battery can be incorporated in a glasses-type device 400 as illustrated in FIG. 8A. The glasses-type device 400 includes a frame 400a and a display portion 400b. A secondary battery is incorporated in a temple of the frame 400a having a curved shape, whereby the glasses-type device 400 can be lightweight, have a well-balanced weight, and be used continuously for a long time. The thin-film-type secondary battery described in Embodiment 1 may be included, and thus a structure that can support space saving due to a reduction in the size of a housing can be achieved.

Furthermore, the secondary battery can be incorporated in a headset-type device 401. The headset-type device 401 includes at least a microphone portion 401a, a flexible pipe 401b, and an earphone portion 401c. The secondary battery can be provided in the flexible pipe 401b or the earphone portion 401c. The thin-film-type secondary battery described in Embodiment 1 may be included, and thus a structure that can support space saving due to a reduction in the size of a housing can be achieved.

The secondary battery can also be incorporated in a device 402 that can be directly attached to a human body. A secondary battery 402b can be provided in a thin housing 402a of the device 402. The thin-film-type secondary battery described in Embodiment 1 may be included, and thus a structure that can support space saving due to a reduction in the size of a housing can be achieved.

The secondary battery can also be incorporated in a device 403 that can be attached to clothing. A secondary battery 403b can be provided in a thin housing 403a of the device 403. The thin-film-type secondary battery described in Embodiment 1 may be included, and thus a structure that can support space saving due to a reduction in the size of a housing can be achieved.

Furthermore, the secondary battery can be incorporated in a belt-type device 406. The belt-type device 406 includes a belt portion 406a and a wireless power feeding and receiving portion 406b, and the secondary battery can be incorporated in the belt portion 406a. The thin-film-type secondary battery described in Embodiment 1 may be included, and thus a structure that can support space saving due to a reduction in the size of a housing can be achieved.

The secondary battery can also be incorporated in a watch-type device 405. The watch-type device 405 includes a display portion 405a and a belt portion 405b, and the secondary battery can be provided in the display portion 405a or the belt portion 405b. The thin-film-type secondary battery described in Embodiment 1 may be included, and thus a structure that can support space saving due to a reduction in the size of a housing can be achieved.

The display portion 405a can display various kinds of information such as reception information of an e-mail or an incoming call in addition to time.

Since the watch-type device 405 is a type of wearable device that is directly wrapped around an arm, a sensor that measures pulse, blood pressure, or the like of a user can be incorporated therein. Data on the exercise quantity and health of the user can be stored and used for health maintenance.

The watch-type device 405 illustrated in FIG. 8A is described in detail below.

FIG. 8B illustrates a perspective view of the watch-type device 405.

FIG. 8C illustrates a side view of the watch-type device 405. FIG. 8C illustrates a state where a thin-film-type secondary battery 913 is incorporated inside. The thin-film-type secondary battery 913 is the secondary battery illustrated in FIG. 7A. The thin-film-type secondary battery 913, which is small and lightweight, is provided at a position overlapping with the display portion 405a.

### REFERENCE NUMERALS

45: substrate holding portion, 47: exhaust mechanism, 48: exhaust mechanism, 49: exhaust mechanism, 50: substrate, 51: stage, 52: substrate transfer mechanism, 53: substrate transfer mechanism, 54: substrate transfer mechanism, 55: evaporation material, 56: evaporation source, 57: heater, 58: evaporation boat, 61: arm, 62: arm, 63: imaging unit, 65: rotation mechanism, 67: film thickness measurement mechanism, 68: shutter, 69: shutter for evaporation sources, 70: load lock chamber, 71: transfer chamber, 72: transfer chamber, 73: transfer chamber, 74: film formation chamber, 80: gate, 81: gate, 82: gate, 83: gate, 84: gate, 85: gate, 86: gate, 87: gate, 88: gate, 91: mask alignment chamber, 92: film formation chamber, 93: heating chamber, 94: second material supply chamber, 95: first material supply chamber, 96: third material supply chamber, 201: positive electrode current collector, 202: solid electrolyte layer, 203: negative electrode current collector, 204: positive electrode active material layer, 205: negative electrode active material layer, 206: protective layer, 212: solid electrolyte layer, 213: negative electrode current collector, 400: glasses-type device, 400a: frame, 400b: display portion, 401: headset-type device, 401a: microphone portion, 401b: flexible pipe, 401c: earphone portion, 402: device, 402a: housing, 402b: secondary battery, 403: device, 403a: housing, 403b: secondary battery, 405: watch-type device, 405a: display portion, 405b: belt portion, 406: belt-type device, 406a: belt portion, 406b: wireless power feeding and receiving portion, 510: positive electrode lead electrode, 511: negative electrode lead electrode, 913: secondary battery, 3000: card, 3001: thin-film-type secondary battery, 3002: ID, 3003: photograph, 3004: IC, 3005: radio wave

1. A manufacturing apparatus for a solid-state secondary battery, comprising:
a mask alignment chamber;
a first transfer chamber connected to the mask alignment chamber;
a second transfer chamber connected to the first transfer chamber;
a first film formation chamber connected to the second transfer chamber;
a third transfer chamber connected to the first transfer chamber; and
a second film formation chamber connected to the third transfer chamber,
wherein the first film formation chamber has a function of forming a positive electrode active material layer or a negative electrode active material layer by a sputtering method,
wherein the second film formation chamber has a function of forming a solid electrolyte layer by co-evaporation of a lithium complex silicon oxide, and
wherein a substrate is transferred between the mask alignment chamber and the first film formation chamber and between the mask alignment chamber and the second film formation chamber without being exposed to the air.

2. The manufacturing apparatus for a solid-state secondary battery according to claim 1, further comprising a heating chamber connected to the second transfer chamber.

3. The manufacturing apparatus for a solid-state secondary battery according to claim 1, wherein the lithium complex is 8-hydroxyquinolinato-lithium.

4. A method for manufacturing a solid-state secondary battery, comprising:
forming a first conductive layer over and in contact with an insulating surface;
forming a negative electrode active material layer over the first conductive layer;
forming a solid electrolyte layer over the negative electrode active material layer by co-evaporation of a lithium complex and silicon oxide;
forming a first positive electrode active material layer over the solid electrolyte layer;
forming a second conductive layer over and in contact with the insulating surface and over the first positive electrode active material layer; and
forming a second positive electrode active material layer over the second conductive layer,
wherein the solid electrolyte layer is in contact with a side surface of the negative electrode active material layer,
wherein the second conductive layer is in contact with a side surface of part of the solid electrolyte layer, and
wherein the first positive electrode active material layer and the second positive electrode active material layer do not overlap with each other.

5. The method for manufacturing a solid-state secondary battery according to claim 4, wherein the lithium complex is 8-hydroxyquinolinato-lithium.

6. The method for manufacturing a solid-state secondary battery according to claim 4, wherein a same sputtering target is used for the first positive electrode active material layer and the second positive electrode active material layer.

7. The method for manufacturing a solid-state secondary battery according to claim 4, wherein a same sputtering target is used for the first conductive layer and the second conductive layer.
